(19) United States
(12) Patent Application Publication
(10) Pub. No.: US 2025/0056737 A1
(43) Pub. Date: Feb. 13, 2025

(54) HOUSING FOR A CIRCUIT BOARD AND ELECTRIC CIRCUIT ARRANGEMENT

(71) Applicant: Lisa Dräxlmaier GmbH, Vilsbiburg (DE)

(72) Inventors: Michael WORTBERG, Dorfen (DE); Michael PFEIFFER, München (DE); Martin SEIDENSCHWAND, Landshut (DE)

(73) Assignee: Lisa Dräxlmaier GmbH, Vilsbiburg (DE)

(21) Appl. No.: 18/929,963

(22) Filed: Oct. 29, 2024

Related U.S. Application Data
(63) Continuation of application No. PCT/EP2023/060028, filed on Apr. 18, 2023.

(30) Foreign Application Priority Data
May 2, 2022 (DE) 10 2022 110 627.6

(51) Int. Cl. H05K 5/00; H05K 7/20

(52) U.S. Cl. CPC H05K 5/006; H05K 5/0069; H05K 7/20409

(57) ABSTRACT

A housing and a circuit arrangement includes a housing body that features an electrically conductive housing base element and a housing wall element. The housing body is coated with an electrically insulating cladding layer. The housing includes a fastening device that has an electrically conductive contacting unit and a mechanical attaching unit. The electrically conductive contacting unit, in the intended installation position, is directly electrically contacted with the housing body at the electrical contacting point, extends into the circuit board compartment and is also arranged so as to be electrically conductively contacted in the circuit board compartment with a corresponding contacting unit of the circuit board. The mechanical attaching unit is arranged to be mechanically connected in the circuit board compartment to a corresponding attaching unit of the circuit board in order to mechanically affix the circuit board in the circuit board compartment.

### CROSS-REFERENCE TO RELATED APPLICATIONS

This application is a continuation of International Application No. PCT/EP2023/060028, filed on Apr. 18, 2023, which claims priority to and the benefit of DE 10 2022 110 627.6 filed on May 2, 2022. The disclosures of the above applications are incorporated herein by reference.

### FIELD

The present disclosure relates to a housing configured for receiving and holding in place a circuit board.

### BACKGROUND

The statements in this section merely provide background information related to the present disclosure and may not constitute prior art.

A vehicle on-board electrical system or vehicle power supply system of a motor vehicle manufactured according to a modern vehicle architecture includes the use of electronic distributors, by means of which an interference-free 12-volt voltage can be made available for devices (so-called vehicle electrical system participants) connected to the vehicle on-board electrical system. During the manufacturing of motor vehicles, a wiring set of the vehicle on-board electrical system may be installed, that is, a so-called wiring harness, in the vehicle. Since the wiring set penetrates a structural element of the motor vehicle at least at one transition point of the motor vehicle, which sections off a wet area (for example, an engine compartment) from a dry area (for example, an interior space), it is desirable that moisture does not travel along the wiring set (that is, through the structural element) from the wet area into the dry area.

To date, it has been known to produce or manufacture a wiring set for a motor vehicle completely outside of the body frame of the motor vehicle. The fully produced/manufactured wiring set is then brought into the body frame of the motor vehicle and laid there so that branches of the wiring set end at the corresponding locations at which the vehicle on-board electrical system participants are or will be installed. Then the vehicle on-board electrical system participants and the wiring set are electrically connected to one another in that coupling elements (plugs and/or connectors) on the side of the wiring set, above which the branches of the wiring set end, are coupled to coupling elements on the side of the vehicle on-board electrical system participants. This approach is associated with significant expense, since modern wiring sets are particularly heavy and are consequently difficult to handle. In addition, at least one branch of the wiring set must be laid through the transition point of the structural element, which is cumbersome to seal using a sealing device, for example, a sealing compound, a sealing grommet, etc. The sealing device must cling particularly close to the lines of the wiring set on the side of the internal circumference, which is particularly difficult to realize. A particularly large number of successive or mutually dependent manipulations or sub-processes are consequently used in order to lay a conventional wiring set in the body frame of the motor vehicle and electrically connect it to vehicle on-board electrical system participants, distributors, etc.

### SUMMARY

This section provides a general summary of the disclosure and is not a comprehensive disclosure of its full scope or all of its features.

The present disclosure provides a means for the laying of the wiring set in a body frame of a motor vehicle in a particularly easy and/or economic manner. The present disclosure additionally relates to an electric and/or electronic circuit arrangement with such a housing and with one or more circuit boards. The housing or the electric/electronic circuit arrangement are provided in particular for a motor vehicle. During the manufacturing of motor vehicles, it becomes furthermore desired to install a wiring set of the vehicle on-board electrical system, that is, a so-called wiring harness, in the vehicle in a particularly simple and inexpensive manner.

In a first aspect of the present disclosure is proposed a housing that is arranged for receiving and holding in place one electric/electronic circuit board or several electric/electronic circuit boards. The housing can be, for example, part of an electronic or electric circuit arrangement having the circuit board or circuit boards that is/are affixed in intended installation position by means of the housing, in particular in the housing. The electric/electronic circuit board is in particular an electric distribution unit having further electric and/or electronic components, for example, in order to protect the electrical energy (voltage and/or current) to be distributed from electrical interferences, and/or to remove electrical disturbances from the electrical energy to be distributed etc. during operation of the circuit arrangement.

The housing features a housing body, which in turn exhibits a housing base element and a housing wall element protruding from the housing base element. The housing base element and the housing wall element together enclose here an angle that is in particular different from 180° and different from 0°. It is in particular provided that the housing base element and the housing wall element together enclose a right angle, which means that the housing wall element is arranged vertically with respect to the housing base element.

The housing base element is electrically conductive as it has an electrically conductive material, for example, copper, aluminum, etc., for example, is made of it or is externally coated with it. It can further be provided that both the housing base element as well as also the housing wall element are configured to be electrically conductive. Accordingly, the housing body is an electrical conductor element, which can be designated, for example, as a busbar.

The housing further features an electrically insulating cladding layer with which the housing body is coated. This means that the housing base element and the housing wall element are externally covered with the cladding layer. The housing also exhibits one predetermined electrical contact point or several predetermined electrical contact points, which is/are free from the cladding layer. For this purpose, it can be conceived that the housing body—that is, the busbar—was initially entirely or partially covered with the cladding layer, in particular encapsulated or molded on, whereupon the cladding layer has been removed again only at the contacting point or contacting points. It is naturally equally conceivable that the contacting points are kept free from the cladding layer and not sprayed on with it first in advance. Accordingly, the electrical contacting points are exempt from the cladding layer. A material of the cladding layer is, for example, a thermoplastic, such as polypropylene, polyamide, etc., or another electrically insulating plastic that can be cast or injection molded in a processing state and is dimensionally stable in a final state. The cladding layer of the housing, which abuts directly against the housing body, is formed in the (for example, cured or cooled) final state of the plastic applied onto the housing body.

A circuit board compartment is formed by the housing; the circuit board compartment is delimited by the housing base element coated with the cladding layer and the housing wall element coated with the cladding layer. The circuit board compartment is arranged for the purpose of receiving or accommodating one or several electric and/or electronic circuit board. For this purpose, the circuit board compartment features at least one compartment region which corresponds in terms of shape and size to the circuit board to be received. The housing is thus arranged—that is, configured and arranged—so as to function as housing for the circuit board or circuit boards.

The respective circuit board has an electric and/or electronic functional circuit. For this purpose, the circuit board comprises, for example, a mostly rigid circuit board body made from an electrically insulating material, having an electrically conductive busbar network, which is configured, for example, by means of an etching method or a printing method, etc., and ends at land patterns and/or has land patterns. Using land patterns (which are also called footprints), an electric and/or electronic component soldered therewith is mechanically held in place, on the one hand, on the circuit board body and electrically contacted, on the other hand, with the conductor path network. The electric and/or electronic functional circuit is formed thereby on/in the circuit board body.

The housing furthermore features one fastening device or several fastening devices, wherein the (respective) fastening device exhibits an electrically conductive contacting unit and a mechanical attaching unit. The electrically conductive contacting unit and the mechanical attaching unit are configured jointly in a unit, which means that the contacting unit and the attaching unit are at least partially identical. In other words: the contacting unit and the attaching unit share at least one common component.

The electrically conductive contacting unit is in its intended installation position—that is, if the contacting unit is positioned as intended and a circuit board is arranged in the circuit board compartment—the electrically conductive contacting unit is in direct electrical contact with the housing body, in particular with the housing base element, at the electrical contacting point. This means that the contacting unit is in at least direct contact with the housing body or is connected to the housing body at the contacting point that is free from the cladding layer. At any rate, the contacting unit extends into the circuit board compartment in the intended installation position and is furthermore configured to be electrically conductively contacted and/or connected in the circuit board compartment with a corresponding contacting unit of the circuit board. Because the contacting unit extends into the circuit board compartment, it additionally functions especially as a spacer element via which the circuit board and the housing body, for example, the housing base element, are spaced from each other. A particularly efficient heat transfer is provided between the contacting unit and the housing body, whereby a particularly efficient heat transfer is provided as a result between the circuit board and the housing body. The circuit board (in particular electric/electronic components attached thereon/thereto) can hereby be particularly efficiently cooled.

The mechanical attaching unit is arranged so as to mechanically connect in the circuit board compartment to a corresponding attaching unit of the circuit board in order to mechanically positionally affix the circuit board in the circuit board compartment. If the contacting unit is thus positioned as intended, and a circuit board is arranged in circuit board compartment, the housing body and the circuit board are mutually electrically contacted by means of the fastening device, on the one hand, and mechanically attached to each other—likewise by means of the fastening device—on the other hand.

Because the contacting unit and the attaching unit are configured and/or arranged together in a structural unit, the fastening device is a locally limited unit, by means of which both a mechanical attaching and an electrical contacting can be produced between the circuit board and the housing body within a limited space defined by the outer contour of the fastening device. The fastening device is thus advantageously realized in a particularly compact design and making efficient use of space, which is particularly beneficial for an advantageous packaging. In doing so, the at least one common component that the contacting unit and the attaching unit share has a double functionality; it functions, on the one hand, as component of the contacting unit and, on the other hand, simultaneously as component of the attaching unit. In contrast to a conventional fastening device, whose contacting unit and attaching unit are not configured in a structural unit, the electrical contacting and/or the mechanical installation would thus be omitted with a removal or detachment of the common component of the fastening device. Due to the fastening device, the housing advantageously features particularly few individual components, whereby it can be particularly easily or economically produced and has a particularly uncomplicated structure.

The housing additionally represents a means for designing the laying of a wiring set in a body frame of a motor vehicle particularly simply and/or economically. Due to the housing, it is now possible to produce wiring set modules outside the body frame of the motor vehicle, then lay the wiring set modules in the body frame of the motor vehicle and join these together to form the wiring set by means of the circuit board affixed in the housing. The wiring set is thus only completed in the interior of the body frame of the motor vehicle by the connecting of the wiring set modules to the circuit board(s). The individual wiring set modules weigh here only very little in comparison with a completed wiring set or wiring harness, so that they are particularly easy to operate. Furthermore, such wiring set modules can be particularly easy to produce in a mechanically supported, especially partially or fully automatic manner.

In addition, a particularly flexible or simple possibility which can be adapted to the needs is created to electrically couple or contact the circuit board with the housing body, which is particularly advantageous to provide an especially short electrical conductor path between an electric connection terminal and the electronic/electric components of the circuit board. This leads not only to particularly low generation of waste heat in the active or activated operation of the circuit board, but also to an advantageously particularly small effective antenna surface of the conductor path network of the circuit board. This leads, in turn, to a particularly advantageous electromagnetic compatibility (EMC) of the wiring set, and consequently of a motor vehicle equipped with the wiring set, as well as to a particularly stable and low-interference voltage supply of electronic and/or electric devices connected to the wiring set. It is provided, in particular, that the housing body, in particular already the housing base element on its own, comprises more material mass than the electronic/electric components and the conductor path network of the circuit board together. Thus, a particularly efficient heat sink for deheating or cooling the circuit board is formed by the housing body.

In a further development of the housing, the housing base element is overtopped on both sides along its thickness direction by the housing wall element, whereby the housing base element separates a first partial compartment of the circuit board compartment and a second partial compartment of the circuit board compartment from each other, wherein the fastening device is arranged for mechanically affixing and electrically contacting the circuit board (which is identified in the following as the first circuit board) in one of the partial compartments and a further (second) circuit board in the corresponding other of the partial compartments with the housing body. If a cross sectional surface is considered, whose intersecting plane cuts through the housing along the thickness direction of the housing base element, a cross sectional figure in the form of a double-T is seen, whose longer leg is represented by the housing base element and whose shorter leg is represented by the housing wall element. The circuit board compartment thus comprises the two partial compartments and is accordingly formed by the two partial compartments. Here, the housing base element traverses the circuit board compartment in such a way that, over a first broad side of the housing base element, one of the partial compartments is adjacent to the housing base element, wherein over a second broad side of the housing base element the corresponding other of the partial compartments is adjacent to the housing base element. The two broad sides are here spaced from each other by a thickness of the housing base element and are opposite each other or face away from each other. It can be provided that the two partial compartments are configured—that is, formed and disposed—mirror-symmetric with respect to each other. The inner surfaces of the partial compartments can differ from each other, for example, in that the cladding layer is shaped differently for each partial compartment.

If there is the need to produce an electrical connection through a structural element of the body frame of the motor vehicle by means of the wiring set, the housing is configured as a sealing device for a through opening of a structural element of a body frame of the motor vehicle according to a further possible example. The housing can be placed, for example, on/in a through opening that penetrates the structural element, wherein the through opening is sealed by placing the housing on/in the housing in its intended installation position on/in the structural element. For this purpose, the housing has, for example, a size and geometry that corresponds to the through opening, so that the housing can be suitably inserted into the through opening, and in particular can be attached there in a non-positive, positively locked, and/or positively bonded manner. For this purpose, the through opening and the housing are in particular configured in such a way that an outer circumferential surface of the housing and an inner circumferential surface of the through opening, for example, abut directly against each other when the housing is placed as intended in/on the through opening. The structural element of the body frame of the motor vehicle is, for example, a bulkhead or end wall, by means of which a wet area, for example, an engine compartment, and a dry area, for example, an interior space, are/will be differentiated from each other. The wiring set having the housing and/or the circuit arrangement produces an electrical connection through the structural element in that corresponding wiring set modules on the side of the wet area and on the side of the dry area are electrically coupled to the housing or to the circuit arrangement, that is, to at least one of the circuit boards.

A housing cover element that seals the circuit board compartment on the side of the wet area is provided in order to inhibit that the circuit arrangement, in particular the circuit board that is affixed on the side of the wet area in the circuit board compartment, that is, in the corresponding one of the partial compartments, to protect from the undesirable effect of moisture. The housing cover element will be described in more detail below.

An efficient possibility is created by means of the housing to further support the modular production of the wiring set. Because the housing acts, on the one hand, as seat for the circuit board or circuit boards, and thus as coupling, loop-through, and/or distributor part for the wiring set modules. On the other hand, the housing acts as the sealing device, by means of which the wet area and the dry area can be effectively sealed from each other. Thus—although an electrical connection is produced through the structural element—moisture does not travel in an undesirable manner along the wiring set (that is, through the structural element) from the wet area into the dry area.

According to a further possible example of the housing, the contacting unit of the fastening device features an electrically conducting sleeve element, by means of which a (first) contacting element of the contacting unit is formed, wherein the sleeve element is in direct contact with the contacting point in the intended installation position via a first sleeve end, and protrudes with a second sleeve end into the circuit board compartment—that is, into one or both of the partial compartments. The attaching unit of the fastening device features here a threaded bolt element corresponding with the sleeve element, by means of which a (first) attaching element of the attaching unit is formed, and which is arranged coaxially with the sleeve element and held in place with respect to the housing body in the intended installation position. The threaded bolt element can be configured so as to be electrically conducting or electrically insulating. A particularly simple possibility for thermally/thermodynamically and/or electrically coupling the circuit board to the housing body and thereby hold the circuit board at a predetermined distance (namely over the sleeve length) from the housing body and/or the cladding layer is provided by the sleeve element.

According to one possible example, it is conceivable that the sleeve element, which is referred to in the following as first sleeve element, and the housing body are connected to each other with the fastening device in a non-positive, positively locked, and/or positively bonded manner, and are especially configured together as one piece. For example, the first sleeve element and the housing body can be configured attached cohesively to each other and made from the same raw material block, for example, by milling. Furthermore a generative production method is conceivable, by means of which the housing body and the first sleeve element are formed cohesively connected to each other in a common production process. In this way, a first sleeve element is advantageously secured against loss, and a housing body particularly with few parts is provided, whereby the operation thereof in particular during a manufacturing of the housing or wiring set is particularly simple and economic. In addition, a particularly low-loss current conductivity as well as a particularly low-loss heat conductivity are given as a result of the particularly intimate connection between the first sleeve element and the housing body.

In a further possible example, the electrically conductive sleeve element (which is identified in the following as second sleeve element) and the housing body are initially loose with respect to each other (or are initially loosely connected to each other) with the fastening device, wherein the second sleeve element is tightened at the contacting point in the intended installation position by means of the bolt element and is thereby brought into electric contact with the housing body. The fastening device and/or at least another of the fastening devices can feature the second sleeve element.

The present description of the fastening device, which exhibits the contacting unit with the first sleeve element and/or with the second sleeve element, is to be understood instead as meaning that the fastening device can exhibit the first sleeve element or the second sleeve element or can exhibit the first as well as also the second sleeve element.

In addition—if two or more fastening devices are available—one or several of the fastening devices can feature the first and/or the second sleeve element. Furthermore, one of the fastening devices can exhibit the first sleeve element, in which one or several of the remaining fastening devices can exhibit the second sleeve element.

In any case, the sleeve element and the threaded bolt element can be configured together as one piece. The first sleeve element, the threaded bolt element, and the housing body can be especially configured together as one piece. In such a case, the threaded bolt element extends away from the sleeve element into the circuit board compartment, so that the circuit board can be secured in the circuit board compartment by means of a nut.

The threaded bolt element is particularly a screw, that is, the threaded bolt element features a threaded bolt portion, and a clamping head portion connected thereto in a positively bonded manner. The housing body, in particular the housing base element and/or the first sleeve element, can feature a threaded hole corresponding with the threaded bolt portion, so that the threaded bolt element can be screwed into the housing body and/or into the first sleeve element by means of a threaded connection. It is alternatively also conceivable that the housing body and/or the first sleeve element exhibit a thread-free through hole that corresponds with the threaded bolt portion, passing through which the threaded bolt portion can be arranged. The latter then protrudes out of the circuit board compartment or out of one of the partial compartments and can be screwed with a corresponding nut outside of the circuit board compartment or in the corresponding other one of the partial compartments. Other examples of the threaded bolt element, for example, as a threaded rod, as a threaded stud, etc., in connection with corresponding screw tightening elements, such as nuts, etc., can likewise be implemented. If the sleeve element is the second sleeve element, it can have a thread-free through opening along its longitudinal extension direction, so that the second sleeve element can be pushed onto the threaded bolt portion of the threaded bolt element.

According to a further possible example, the fastening device and/or optionally one or several of the further fastening devices can feature an electrically conductive flag, by means of which another (second) contacting element of the contacting unit is formed, wherein the flag and the housing body are electrically contacted with each other, and the flag protrudes perpendicularly and free from the cladding layer into the circuit board compartment (that is, into one of the partial compartments), so that the contacting point of the housing body is formed by the flag. At the same time, the attaching unit of the fastening device features a predetermined connecting portion of the flag, by means of which another (second) attaching element of the attaching unit is formed, in which the connecting portion of the flag is configured so as to be mechanically and electrically conductively connected to a corresponding connecting portion of the circuit board. In this respect, the flag is configured rigid enough or inherently stable enough that the circuit board attached thereto is held by the flag securely or stably against the housing body. The mechanical installation and the simultaneous electrical connection of the circuit board to the flag is carried out in particular by clinching (also called clinching), by means of another welding method, by means of soldering, etc. For this purpose, the flag of the housing or housing body and a terminal flag of the circuit board mutually correspond to each other, so that the flags—as soon as the circuit board is positioned in the circuit board compartment or in the corresponding one of the partial compartments—are arranged surface-parallel to each other, in particular contact each other flatly in the region of the connecting portion of the flag of the housing. The flag of the housing and the terminal flag of the circuit board can then be joined to each other by means of a welding tool, in particular by means of clinching pliers, whereby the circuit board is connected via the flag to the housing body in an electrically conductive and heat conductive manner and is simultaneously mechanically affixed in/on the housing. Because of this, the housing is suited for particularly simple inserting and connecting the circuit board and consequently for particularly easily producing the wiring set featuring the circuit arrangement.

According to a further possible example, the housing body, in particular its housing base element, and the flag are configured together as one piece or are otherwise connected to each other in a non-positive, positively locked, and/or positively bonded manner in order to be able to produce a particularly efficient or low-loss electrical and thermal contact between the circuit board and the housing body. It can be provided, for example, that the flag is configured as a flexible element that is bent out from the housing body so that the flag or the flexible element projects into the circuit board compartment or into the partial compartment from one of the broad sides of the housing base element.

According to one possible further development of the housing, the fastening device and/or optionally one or several of the further fastening devices can feature an electrically conductive soldering base with a screw element, which is formed by another (third) contacting element of the contacting unit. The soldering base is arranged so as to be soldered to a corresponding soldering base receptacle of the circuit board (that is, to one of the circuit boards, if more than one circuit board is present). In the intended installation position, the soldering base is contacted directly over a base surface at the contacting point. The soldering base is further configured to be electrically and mechanically connected to the conductor path network of the circuit board, in particular by means of one land pattern or several land patterns. This means that the (respective) circuit board can feature one such land pattern or several such land patterns. The attaching unit of the fastening device can feature a screw tightening element corresponding with the screw element, which is formed by another (third) attaching element of the attaching unit. The screw tightening element or the third attaching element is configured for tightening the base surface against the contacting point.

The respective soldering base can exhibit an internally threaded hole, wherein the screw tightening element can then be, for example, a screw with a threaded bolt portion corresponding with the internally threaded hole, and a clamping head portion connected therewith in a positively bonded manner. The screw tightening element can alternatively exhibit a threaded rod corresponding with the internally threaded hole, and a nut corresponding with the threaded rod. It is furthermore conceivable that the screw tightening element has only one nut, whereby a threaded stud that corresponds with the nut then protrudes from the soldering base.

A particularly reliable possibility for positionally holding the circuit board reliably in the circuit board compartment and coupling it to the housing body in an electrically conductive manner as well as with respect to thermal energy is created by means of the soldering base.

In a further possible example of the housing, it is provided that the housing wall element is configured to be electrically conductive and is electrically contacted with the housing base element and features a terminal element for the electrically connecting of the housing base element to an electrical energy supply network. The housing base element and at least one part of the housing wall element can be connected with each other in a non-positive, positively locked, and/or positively bonded manner, or can be configured together as one piece. The electrical energy supply network is in particular a 12-volt supply electrical system of the motor vehicle, in which the housing or the circuit arrangement is used. Accordingly, the circuit arrangement can be a vehicle on-board electrical system participant. Because the housing body is connected to the electrical energy supply network in the intended installation and connection position, electrical energy can be provided to the circuit arrangement in the circuit board compartment via the housing body. Depending on the positional arrangement of the contacting points or fastening device or fastening devices, a conductor path segment between an electrical terminal point of the circuit arrangement or circuit board and electrical and/or electronic components of the circuit arrangement or circuit board can be advantageously configured particularly short. This leads to a particularly efficient operation of the circuit arrangement or circuit board, and to a particularly advantageous EMC quality of the wiring set and/or of the circuit arrangement or circuit board.

In order to be able to particularly efficiently cool the circuit arrangement or circuit board disposed in the circuit board compartment, the housing features—according to a further possible example—a cooling rib assembly having one cooling rib or several cooling ribs, wherein the respective cooling rib extends outwardly away from the housing body, in particular from the housing wall element.

The respective cooling rib can be formed entirely from the material of the cladding layer. In other words: the respective cooling rib can be formed completely from the material of the cladding layer. The cooling rib can be formed, for example, when the cladding layer is formed. This means that the cooling rib and the cladding layer can be formed together as one piece. It can alternatively be provided that the cooling rib and the cladding layer were produced separately from one another and were then attached in a non-positive, positively locked, and/or positively bonded manner.

As an alternative, the cooling ribs can feature a material different from that of the cladding layer. For example, the cooling rib can be externally applied onto the cladding layer, for example, over sprayed onto the cladding layer and/or attached onto the cladding layer in a non-positive, positively locked, and/or positively bonded manner, or molded onto the cladding layer.

A cooling rib core of the cooling rib and the housing body can be mutually contacted for heat conduction, wherein the cooling rib core is encased in an electrically insulating material. For example, a material of the cooling rib core can be a metal, in particular the same metal as that of the housing body. The cooling rib body and the housing body can be contacted or connected to each other in a heat conducting manner in that they are connected in a non-positive, positively locked, and/or positively bonded manner, or are configured together as one piece. The electrically insulating material is, for example, the material of the cladding layer. In this regard, the cooling rib body can be encased or coated with the material of the cladding layer when the cladding layer is created. In this regard, the cooling rib body can be viewed as a component of the housing body.

A further possible example of the housing provides that it features the housing cover element, which is arranged for a fluidically tight sealing of the circuit board compartment and features a plug contact region, by means of which plug contacts of the circuit board can be electrically contacted—directly or indirectly—outside of the circuit board compartment. The housing cover element is thus configured to be placed in such a way in/on the circuit board compartment, in particular in/on one of the partial compartments, that the circuit board compartment or partial compartment is fluidically sealed against an environment. For this purpose, the housing cover element corresponds in terms of shape and size with the circuit board compartment, that is, with an opening of the circuit board compartment, through which the circuit board is inserted into the circuit board compartment.

The housing cover element exhibits a first side which faces the circuit board compartment or the corresponding partial compartments in the intended installation position, that is, when the circuit board compartment is sealed by the housing cover element against its environment. In addition, the housing cover element features a second side which faces away from the circuit board compartment or the corresponding of the partial compartments in the intended installation position. On this first side, the housing cover element can exhibit a plug on the side of the circuit board compartment. As an alternative or in addition thereto, the housing cover element can exhibit a socket on the side of the circuit board compartment on its first side. In any case, the plug or the socket corresponds with the plug contacts of the circuit board. Accordingly the plug contacts of the circuit board can exhibit plug elements that correspond with socket elements of the socket of the housing cover element. As an alternative or in addition thereto, the plug contacts of the circuit board can feature socket elements that correspond with plug elements of the plug of the housing cover element.

On the second side of the housing cover element, it can feature a socket and/or plug on the environment side, wherein the sockets and/or plug elements on the environment side correspond with the sockets or plug elements on the wiring set module side. The sockets and/or plug elements on the environment side and socket and plug elements on the side of the circuit board compartment are respectively mutually electrically conductively connected. The plug contacts of the circuit board can thus be contacted indirectly outside of the circuit board compartment or the corresponding partial compartment.

It is furthermore conceivable that the housing cover element is free from its own plug and socket elements, and the plug contacts of the circuit board extend through the housing cover element and end thereby on the side of the environment. The plug contacts of the circuit board can thus be contacted directly outside of the circuit board compartment or the corresponding partial compartment. For this purpose, the plug contact region of the housing cover element can exhibit, for example, a predetermined puncture point (for example, made of a reversibly elastic, for example, rubber-like material), wherein then the plug contacts of the circuit board puncture the predetermined puncture location with an intended applying of the housing cover, and thus end on the side of the environment of the housing and can be directly contacted there. A reliable sealing effect is provided here along the plug contacts as a result of the material of the predetermined puncture point, which clings to the plug contacts.

In addition, the housing cover element can exhibit a plug backing that corresponds with a plug backing on the side of the wiring set module so that the corresponding wiring set module and the housing cover element can be attached to each other in a non-positive, positively locked, and/or positively bonded manner. Thus, the plug contacts of the circuit board and the corresponding wiring set module can be electrically contacted by means of a simple mechanical coupling of the plug backings. As an alternative or in addition to the predetermined puncture point, the housing cover element can feature a through opening, through which the plug contacts of the circuit board end on the environment side when the housing cover element is/will be inserted as intended. A sealing effect along the plug contacts is then provided via the plug backings, which exhibit for this purpose, for example, a sealing element, for example, an O-ring, etc.

As a result of the housing cover element, the housing can be particularly advantageously used as the sealing device between the wet area and the dry area of the body frame of the motor vehicle. It is provided here, especially because of the housing cover element, that the circuit arrangement or the circuit board that is affixed in a region of the circuit board compartment that opens into the wet area is reliably protected from being sprayed with a liquid, in particular water. An undisturbed operation of the circuit arrangement itself is then provided when the circuit board or one of the circuit boards has been or is arranged in the circuit board compartment or partial compartment on the side of the wet area.

In a further possible example of the housing, it features, especially in its housing base element, a through opening through which electrically conductive signal coupling elements are guided in a coupling region, by means of which a circuit board that can be affixed in the first partial compartment and a further circuit board that can be affixed in the second partial compartment can basically be electrically coupled to each other. Thus, an electrical and/or electronic unit can be formed with the aid of the housing in a particularly easy manner—and in an especially advantageously manner for a packaging—from the two circuit boards to be electrically coupled or coupled to each other.

One or several of the signal coupling elements is/are configured—according to a further possible example—as a connecting bond element. This means that the circuit boards are electrically connected to each other by means of wire bonding or strip bonding. This is advantageous since the bonding can be particularly versatilely and flexibly used, and in particular the conductor path networks can be connected to each other with connecting bonds extending in three dimensions. A particularly good design and/or arrangement freedom is provided thereby for designing or arranging of the (respective) circuit board. Boundary conditions (possibly resulting from packaging desires) can thereby be reacted to in a particularly targeted manner. Furthermore, the bonding can be carried out particularly easily in a partially or fully automated manner, whereby the expense for the manufacturing of the circuit arrangement is reduced and a consistent connection quality is provided.

According to a further development of the housing, one or several signal coupling elements can alternatively or additionally be provided as a press-in contact, which is pressed into a coupling element carrier that is held in the coupling region in the through opening. Here, it can be provided that the coupling element carrier seals the through opening of the coupling region. It is equally easily conceivable that the press-in contacts are pressed individually or groupwise into two or more coupling element carriers, in which the coupling element carriers can be inserted in respectively separately formed through openings or in a common through opening. With the press-in contact is used together with the coupling element carrier, the electrical connection of the circuit boards becomes particularly simple, since the circuit boards here electrically contact each other with a positional arrangement of the circuit boards in the partial compartments. In other words, different processes or manipulations are not needed for positionally arranging the circuit boards and electrically contacting or connecting the circuit boards.

In connection with the signal coupling element, it is to be understood that the housing can either have only connecting bond elements or only press-in contacts. Furthermore, it is to be understood that the housing can have one connecting bond element or several connecting bond elements as well as one press-in contact or several press-in contacts.

In a second aspect of the present disclosure, an electrical and/or electronic circuit arrangement is proposed which features a housing configured according to the above description and one circuit board or several circuit boards. Here the (respective) circuit board is held in the circuit board compartment and is thereby in electrical and thermal contact with the housing body. Thus, the housing functions then as a seat for the circuit board or circuit boards. The circuit board is in particular configured as an electric and/or electronic coupling, loop-through, and/or distributor circuit.

A further possible example of the circuit arrangement comprises a first circuit board and a second circuit board. Here, the housing base element is overtopped along its thickness direction on both sides by the housing wall element, whereby the housing base element differentiates the first partial compartment of the circuit board compartment and the second partial compartment of the circuit board compartment from each other. By means of the fastening device, the first circuit board is mechanically affixed in one of the partial compartments, and the second circuit board is mechanically affixed in the corresponding other one of the partial compartments and is thereby in electrical and mechanical contact with the housing body. In addition, the circuit boards are coupled to each other via the signal coupling elements, wherein an electric and/or electronic unit is formed as a result of the two circuit boards which are coupled to each other. Here, the respective circuit board is to be viewed as a component of the electric and/or electronic unit. For example, the first of the circuit boards forms a first portion of an electronic control unit, in which the second circuit board forms another portion of the control unit. A possibility is thereby provided for configuring an electronic unit, for example, a motor vehicle control unit, in a particularly compact manner.

In a third aspect of the present disclosure, a wiring set for a frame body of the motor vehicle is proposed, which features the circuit arrangement configured according to the above description, and consequently the housing configured according to the above description as a component. In addition, the wiring set exhibits at least one wiring set module that is electrically connected to the circuit board or one of the circuit boards.

Further advantages, features, and details of the present disclosure can be obtained from the following description of possible examples as well as on the basis of the drawings. The features and feature combinations mentioned above in the description as well as the features and feature combinations shown alone below in the description of the figures and/or in the figures can be utilized not only in the respectively indicated combination, but also in other combinations or on their own without leaving the context of the present disclosure.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a schematic and cross-sectional exploded view of the circuit arrangement according to the present disclosure;

FIG. 2 is a schematic and cross-sectional exploded view of the circuit arrangement, wherein the housing features a circuit board compartment comprising two partial compartments, the housing features a housing cover element, and an fastening device of the housing features a sleeve element according to the present disclosure;

FIG. 3 is a schematic and cross-sectional exploded view of the circuit arrangement, wherein the housing has a coupling region with signal coupling elements guided through it, and an fastening device of the housing features a flag according to the present disclosure;

FIG. 4 is a perspective partial view of the circuit arrangement, whose cladding layer is not shown, wherein an fastening device of the housing features a soldering base according to the present disclosure;

FIG. 5 is a schematic view of a circuit board in plan view according to the present disclosure; and

FIG. 6 is a schematic and cross-sectional view of the circuit arrangement, wherein two circuit boards are electrically connected to each other by means of signal coupling elements according to the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

A housing 1, a circuit arrangement 2 having the housing 1 are presented with a joint description in the following. Identical and functionally identical elements are provided with the same reference numerals in the figures.

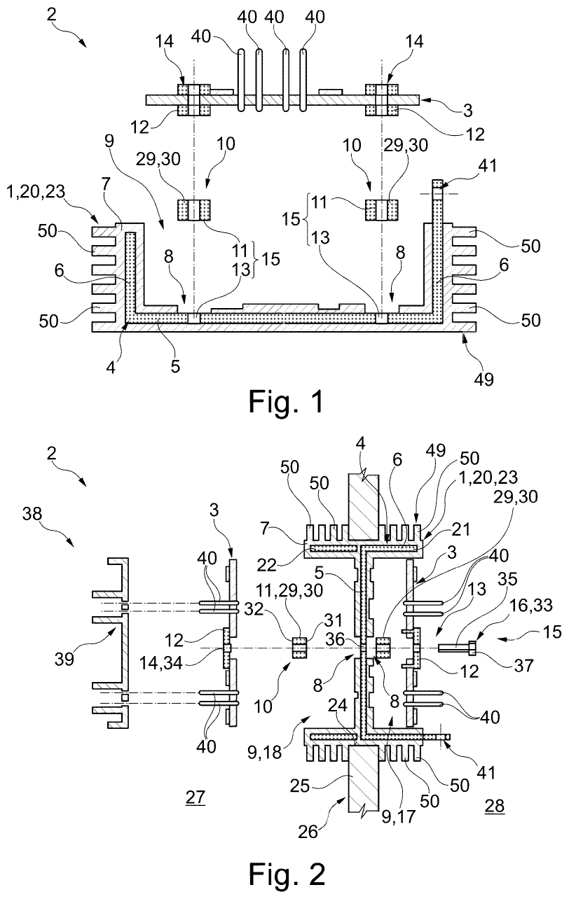

For this purpose, FIG. 1 shows a schematic and sectional view of the circuit arrangement 2 having a circuit board 3 in exploded view. A housing body 4 of the housing 1 exhibits an electrically conductive housing base element 5 as well as a housing wall element 6 protruding therefrom. The housing wall element 6 can be configured as one piece or can include multiple parts. With reference to the figure, it is to be understood herein that the housing wall element can be arranged so as to frame the housing base element 5. An infinitesimally thin layer of the housing body 4 is depicted for reasons of clarity in the sectional view of the figure. The housing 1 also features a cladding layer 7, which is electrically insulating, and is formed in the present case from an electrically insulating thermoplastic, such as polypropylene, polyamide, or the like. The housing body 4 or the housing base element 5 and the housing wall element 6 are coated with the cladding layer 7 with the exception of one predetermined electrical contacting point 8 or several predetermined electrical contacting points 8. In the present case, the housing body 4 is sprayed or spray-coated, or encapsulated—apart from the at least one contacting point 8—with the material of the cladding layer 7.

The housing consequently features a circuit board compartment 9 that is delimited by the housing base element 5 coated with the cladding layer 7 and by the housing wall element 6 coated with the cladding layer 7. The bare housing body 4 adjoins the circuit board compartment 9 at the respective contacting point 8.

It furthermore arises from the figure that the housing can have a cooling rib assembly 49, which in the present case comprises a plurality of cooling ribs 50. The cooling rib assembly 49, that is, the respective cooling rib 50, extends outwardly away from the housing body 4, in particular from the housing wall element 6.

The housing 1 features one fastening device 10 or several fastening devices 10, wherein the circuit board 3 is positionally affixed in the housing compartment 9 by means of the respective fastening device 10. The circuit board 3 and the housing body 4, in the present case the housing base element 6, are simultaneously electrically contacted with each other by means of the respective fastening device 10. For this purpose, the respective fastening device 10 comprises an electrically conductive contacting unit 11, which in the intended installation position is in direct electrical contact with the electrical contacting point 8 with the housing body 4, that is, in the present case with the housing base element 6, and extends into the circuit board compartment 9. The circuit board 3 features here a contacting unit 12 corresponding with the contacting unit 11, wherein the contacting units 11, 12 abut directly against each other or contact each other directly in the intended installation position, so that an electrical contact is produced between the circuit board 3 and the housing body 4.

In addition, the respective fastening device 10 features a mechanical attaching unit 13 of which in FIG. 1 merely an internally threaded opening is shown by way of example which is formed in the housing body 4. The circuit board 3 features here an attaching unit 14 corresponding with the attaching unit 13, wherein the attaching units 13, 14 interact with each other and impart a non-positive, positively locked, and/or positively bonded connection between the circuit board 3 and the housing 1 in the intended installation position, so that the circuit board 3 is mechanically affixed in the circuit board compartment 9.

The contacting unit 11 and the attaching unit 13 are configured together in a unit 15. In other words: the respective fastening device 10 is formed by the unit 15. Thus, the contacting unit 11 and the attaching unit 13 occupy a common installation space that is delimited by the contacting unit 11 or by the attaching unit 13. The contacting unit 11 and the attaching unit 13 of the same unit 15 or the same fastening device 10 share here at least one common component, for example, a threaded bolt element 16 (first shown in FIG. 2). The housing 1 is thus configured for receiving the electrical circuit board 3, holding it in place, and simultaneously electrically contacting with the housing body 4 as a result of the fastening device 10.

In FIG. 2, the circuit arrangement 2 is shown in exploded view in a schematic and sectional view, wherein the housing 1 features a circuit board compartment 9 comprising two partial compartments 17, 18. The housing base element 5 is overtopped here on both sides along its thickness direction by the housing wall element 6, whereby the housing base element 5 delimits from each other the (first) partial compartment 17 of the circuit board compartment 9 and the (second) partial compartment 18 of the circuit board compartment 9. By means of the fastening device 10 or the unit 15 made up of the contacting unit 11 and the attaching unit 13, the (first) circuit board 3 is affixed in the first partial compartment 17, and a further (second) circuit board 19 is mechanically affixed in the second partial compartment 18, and electrically contacted with the housing body 4.

It can furthermore be seen in FIG. 2 that a cross-sectional shape 20 of the housing 1 appears as a double-T (that is, as with an I-profile carrier or double-T carrier known from metal engineering). It can furthermore be seen that the housing wall element 6 can be made up by at least two housing wall element portions 21, 22, wherein one of the housing wall element portions 21, 22, here the housing wall element portion 21, is connected in a positively bonded manner to the housing base portion 5, for example, is formed one piece therewith.

Not exclusively, but in one example in the double compartment example of the housing 1 depicted in the FIGS. 2 to 6, the same is configured so as to function as a sealing device 23 for sealing a through opening 24 of a structural element 25 of a body frame 26 of a motor vehicle. For this purpose, the housing 1 is inserted into the through opening 24, whereby the through opening 24 is sealed by means of the housing 1. The structural element 25 is, for example, an end wall or another bulkhead of the motor vehicle chassis, by means of which a wet area 27, for example, an engine compartment, and a dry area 28, for example, an interior, are delimited from each other.

According to FIG. 2, the contacting unit 11 of the fastening device 10 features, for example, a first contacting element 29 configured as an electrically conductive sleeve element 30 or features such an electrically conductive sleeve element 30. In the intended installation position, the sleeve element 30 is contacted directly with the contacting point 8 of the housing body 4 via a first sleeve end 31, and the sleeve element 30 protrudes with a second sleeve end 32 into the circuit board compartment 9—that is, into one of the partial compartments 17, 18. The attaching unit 13 of the fastening device 10 comprises the threaded bolt element 16, which in the present case corresponds with the sleeve element 30. A (first) attaching element 33 of the attaching unit 13 is then formed by means of the threaded bolt element 16 which is coaxial arranged with the sleeve element 30 and is affixed with respect to the housing body 4. As shown by way of example in FIG. 2, the second circuit board 19 features an internally threaded opening 34 that corresponds with the threaded bolt portion 35 of the threaded bolt element 16. The threaded bolt portion 35 extends furthermore through the contacting unit 12 of the first circuit board 3, through the sleeve element 30, a threadless through hole 36, a further sleeve element 30, and the internally threaded opening 34. The internally threaded opening 34 is formed here in a contacting unit 12 of the second circuit board 19. The circuit boards 3, 19 are each affixed hereby, on the one hand, in the respective partial compartment 17, 18 and tightened toward the housing base element 5. On the other hand, the circuit boards 3, 19 are electrically coupled to each other and each respectively electrically coupled to the housing body 4. A clamping head portion 37 of the threaded bolt element 16 is supported thereby on the contacting unit 12 of the first circuit board 3.

It is furthermore shown in FIG. 2 that the housing 1 can feature a housing cover element 38 configured for fluidically tightly sealing the circuit board compartment 9, in the present case the second partial compartment 18. The housing cover element 38 exhibits a plug contact region 39, by means of which plug contacts 40 of the circuit boards 3, 19 can be electrically—directly or indirectly—contacted outside the circuit board 9. This means that the plug contacts 40 are guided through the plug contact region 39 in the intended installation position, and consequently end in an environment of the housing 1 or of the circuit arrangement 2, for example, in the wet area 27 or in the dry area 28.

The housing wall element 6, in the present case the first housing wall element portion 21, is configured so as to be electrically conductively connected in a positively bonded manner with the housing base element 5 and be consequently electrically contacted. In addition, the housing wall element 6, in the present case the first housing wall element portion 21, has a terminal element 41 for electrically connecting the housing body 4, in particular the housing base element 5, to an electrical energy supply network (not depicted). The terminal element 41 is free of the cladding layer 7. This means that the housing body 4 protrudes from the cladding layer 7 at the location of the terminal element 41. A voltage supply of the circuit boards 3, 19 can thereby be carried out via the housing body 4

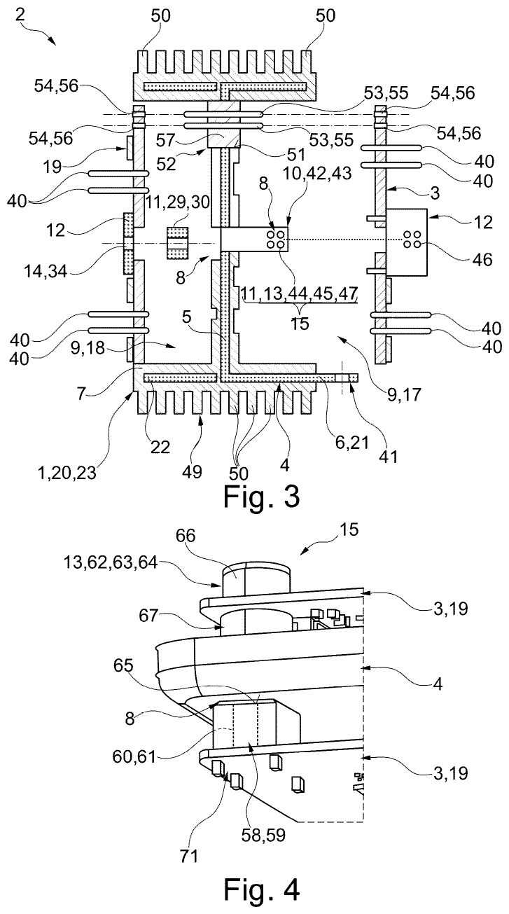

FIG. 3 shows a schematic and sectional view of the circuit arrangement 2 in exploded view, in which the housing 1, namely its fastening device 10, has a flag 42, by means of which another (second) contacting element 43 of the contacting unit 10 is formed. In the present case, the flag 42 and the housing body 4 are configured together as one piece, since the flag is a flexible element that is bent outwardly from the housing base element 5 with respect to the rest of the housing base element 5. The flag 42 and the housing body 4 are thus electrically contacted with each other, wherein the flag protrudes perpendicularly and free from the cladding layer into the circuit board compartment 9. The contacting point 8 of the housing 1 or of the housing body 4 is thus formed by the flag 42.

The attaching unit 13 of the fastening device 10 or the housing 1 comprises a predetermined connecting portion 44 of the flag 42 or is formed by it. Another (second) attaching element 45 of the attaching unit 13 is formed by the connecting portion 44, or the connecting portion 44 exhibits a second attaching element 45 or several second attaching elements 45. The connecting portion 44 of the flag 42 is configured at any rate so as to be mechanically and electrically conductively connected to a corresponding connecting portion 46 of the circuit board 3. In the present example, the fastening device 10 features a plurality of second attaching elements 45 in the contacting region 8, that is, in the connecting portion 44 of the flag 42. In the present case, the at least one attaching element 45 is configured as a clinching or clinch point 47.

The circuit boards 3, 19 feature a terminal flag 48 that corresponds with the flag 42. The flags 42, 48 are arranged—as soon as the circuit board 3 is positioned in the circuit board compartment 9 or in the first partial compartment 17—surface-parallel to each other. The flags 42, 48 especially contact each other flatly in the region of the connecting portions 44, 46. The flag 42 of the housing 1 and the terminal flag 48 of the circuit board 3 are joined to each other by means of a clinching tool. The circuit board 3 is connected thereby in an electrically conductive and heat conducting manner to the housing body 4 via the flag 42, and is simultaneously mechanically affixed in/on the housing 1.

In FIG. 3 is furthermore shown a through opening 51 which penetrates the housing body 4, here the housing base element 5, and which is arranged in a coupling region 52 of the housing body 4. Electrically conductive signal coupling elements 53 extend through the through opening 51; the signal coupling elements 53 end on one side in the first partial compartment 17 and on the other side in the second partial compartment 18. The first circuit board 3 affixed in the first partial compartment 17 and the second circuit board 19 affixed in the second partial compartment 18 are electrically coupled to each other in that the signal coupling elements 53 and thus the corresponding terminal elements 54 of the circuit boards 3, 19 are electrically contacted with each other. For example—and as depicted in FIG. 3—the signal coupling elements 53 can be configured as a respective press-in contact 55, wherein the respective corresponding terminal elements 54 can be configured as a respective press-in contact receptacle 56. The signal coupling elements 53 configured as press-in contact 55 are embedded, for example, pressed into a coupling element carrier 57. This coupling element carrier 57 is inserted in the through opening 51, whereby the through opening 51 is at least partially locked, in particular sealed. In any case, the coupling element carrier 57 is held positionally in and/or by means of the through opening 51 in non-positive, positively locked, and/or positively bonded manner.

FIG. 4 shows a perspective partial view of the circuit arrangement 2, wherein the cladding layer 7 is not depicted. It can be seen in FIG. 4 that the fastening device 10 of the housing 1 features an electrically conductive soldering base 58, by means of which another (third) contacting element 59 of the contacting unit 11 is formed. The soldering base 58 exhibits a screw element 60 configured here as an internally threaded hole 61. The soldering base 58 is soldered to a corresponding soldering base receptacle 71 of the circuit board 3, 19, and is consequently electrically contacted with the circuit board 3, 19 and simultaneously mechanically affixed on/in the circuit board 3, 19. The attaching unit 13 of the fastening device 10 features here a screw tightening element 62 corresponding with the screw element 60, 61, in the present case a screw 63. Another (third) attaching element 64 of the attaching unit 13 is formed by the screw tightening element 62. As depicted in FIG. 4, the circuit boards 3, 19 featuring the soldering base 58 are electrically contacted with the housing body 4 by a base surface 65 of the soldering base 58 being directly or indirectly contacted with the contacting point 8. For this purpose, the screw tightening element 62, in the present case the internally threaded hole 61, is screwed into the screw element 60, whereby the corresponding circuit board 3, 19 is tightened to the soldering base 58 at the contacting point 8. A clamping head portion 66 of the screw tightening element 62 is tightened here on a side of the housing body 4 that is opposite to the side at which the base surface contacts the housing body 4.

In addition to the soldering base 58 and the associated screw tightening element 62, a sleeve 67 through which the screw tightening element 62 extends can be used to electrically contact and simultaneous mechanically affix two circuit boards 3, 19 by means of a single fastening device 10. Here the sleeve 67 is disposed on the side of the housing body 4 opposite to the side at which the base surface contacts the housing body 4. A voltage supply of the circuit boards 3, 19, which at this location is free from the soldering base 68, can thus be carried out via the sleeve 67 (starting from the housing body 4), for which purpose the sleeve 67 is configured so as to be electrically conductive. As an alternative or in addition, it is conceivable to provide electrical voltage to the mentioned circuit board 3, 19 (starting from the housing body 4) via the screw element 60 of the soldering base 58 in connection with the screw tightening element, for which purpose the screw element 60 and the screw tightening element 62 are configured so as to be electrically conductive.

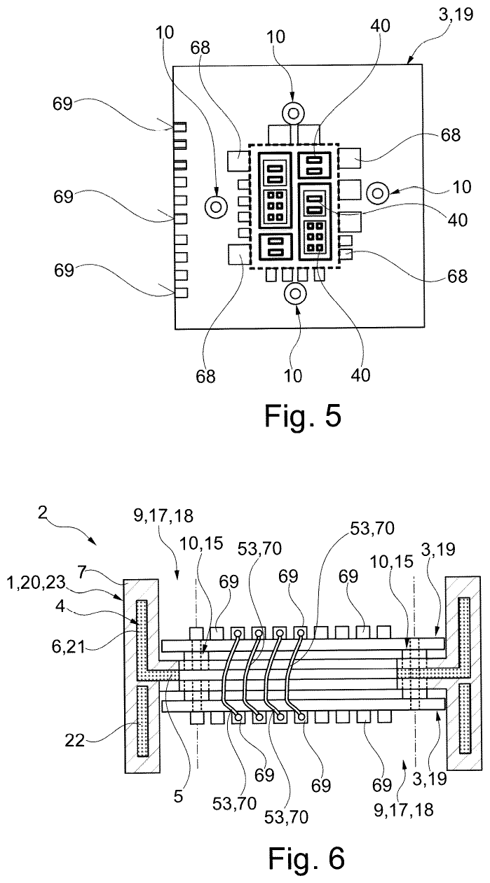

FIG. 5 shows a schematic view of the circuit board 3, 19 in plan view. It can be seen that the circuit arrangement 2 can feature a plurality of fastening devices 10 in order to attach the circuit board 3, 19 in the circuit board compartment 9 and to electrically contact with the housing boy 4. It is to be understood that the (respective) fastening device 10 can possess a plurality of contacting elements 29, 42, 59 and/or a plurality of attaching elements 33, 45, 64. The corresponding contacting units 12 or attaching units 14 of the circuit board 3, 19 are particularly close to electric and/or electronic components 68, in particular metal-oxide-semiconductor field-effect transistors (MOSFETS). A particularly efficient, in particular a low-interference and loss-free voltage supply of the electric and/or electronic components 68 is provided through this.

The circuit boards 3, 19 further feature bond terminals 69, via which the circuit boards 3, 19 can be coupled to each other for the electric signal transfer, as is depicted in FIG. 6. FIG. 6 shows a schematic and sectional view of the circuit arrangement 2, wherein the circuit boards 3, 19 are electrically connected with each other by means of the signal coupling elements 53, wherein the signal coupling elements 53 are configured as connecting bond elements 70.

A respective possibility for overcoming known disadvantages during the production of the wiring harness for motor vehicles is shown by means of the housing 1 and the circuit arrangement 2 having the housing 1.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A housing configured to receive and hold an electric circuit board in place, the housing comprising:
a housing body having an electrically conductive housing base element and a housing wall element protruding from the electrically conductive housing base element, the housing body including an electrical contacting point;
an electrically insulating cladding layer that coats a portion of the housing body that does not include the electrical contacting point;
a circuit board compartment that is delimited by the electrically conductive housing base element and the housing wall element, and the circuit board compartment is coated with the electrically insulating cladding layer; and
a fastening device including:
an electrically conductive contacting unit which is directly electrically contacted with the housing body at the electrical contacting point and extends into the circuit board compartment in an installation position, and is configured to be electrically conductively contacted in the circuit board compartment with a corresponding contacting unit of the electric circuit board; and
a mechanical attaching unit configured to be mechanically connected in the circuit board compartment to a corresponding attaching unit of the electric circuit board in order to mechanically affix the electric circuit board in the circuit board compartment.

2. The housing according to claim 1, wherein the electrically conductive housing base element is overtopped on both sides along a thickness direction of the electrically conductive housing base element by the housing wall element, the electrically conductive housing base element separates a first partial compartment of the circuit board compartment and a second partial compartment of the circuit board compartment from each other, wherein the fastening device is configured to mechanically affix and electrically contact the electric circuit board to the housing body in the first partial compartment and a second electric circuit board in the second partial compartment.

3. The housing according to claim 1, wherein the housing is arranged as a sealing device for sealing a through opening of a structural element of a body frame of a motor vehicle.

4. The housing according to claim 1, wherein:
the electrically conductive contacting unit of the fastening device includes an electrically conductive sleeve element to form a contacting element of the electrically conductive contacting unit, wherein the electrically conductive sleeve element is directly contacted with the electrical contacting point via a first sleeve end and protrudes with a second sleeve end into the circuit board compartment in the installation position; and
the mechanical attaching unit of the fastening device has a threaded bolt element that corresponds with the electrically conductive sleeve element to form an attaching element of the mechanical attaching unit, the attaching element is coaxially arranged with the electrically conductive sleeve element and is fixed in relation to the housing body.

5. The housing according to claim 1, wherein:
the electrically conductive contacting unit of the fastening device includes an electrically conductive flag to form another contacting element of the electrically conductive contacting unit, wherein the electrically conductive flag and the housing body are mutually electrically contacted, and the electrically conductive flag protrudes perpendicularly and free from the electrically insulating cladding layer into the circuit board compartment, wherein the electrical contacting point is formed by the electrically conductive flag; and
the mechanical attaching unit of the fastening device includes a connecting portion of the electrically conductive flag to form a second attaching element of the mechanical attaching unit, wherein the connecting portion of the electrically conductive flag is configured to mechanically and electrically conductively connect with a corresponding connecting portion of the electric circuit board.

6. The housing according to claim 5, wherein the electrically conductive flag and the housing body are configured together as one piece.

7. The housing according to claim 1 wherein:
the electrically conductive contacting unit of the fastening device includes an electrically conductive soldering base having a screw element to form a second contacting element of the electrically conductive contacting unit, wherein the electrically conductive soldering base is configured to be soldered to a corresponding soldering base receptacle of the electric circuit board, and is directly contacted with the electrical contacting point by a base surface in the installation position; and
the mechanical attaching unit of the fastening device includes a screw tightening element corresponding with the screw element to form a second screw attaching element of the mechanical attaching unit, which is configured to tighten the base surface against the electrical contacting point.

8. The housing according to claim 1, wherein the housing wall element is configured to be electrically conductive and is electrically contacted with the electrically conductive housing base element, and the housing wall element has a terminal element configured to electrically connect the electrically conductive housing base element to an electrical energy supply network.

9. The housing according to claim 1, further comprising a cooling rib assembly having a cooling rib and extending outwardly away from the housing body.

10. The housing according to claim 1, further comprising a housing cover element configured to fluidically tightly lock the circuit board compartment, the housing cover element having a plug contact region, the plug contact region configured to electrically contact plug contacts of the electric circuit board outside of the circuit board compartment.

11. The housing according to claim 2, wherein the electrically conductive housing base element has a through opening through which electrically conductive signal coupling elements are guided in a coupling region to install the electric circuit board in the first partial compartment and install the second electric circuit board in the second partial compartment, and the electric circuit board and the second electric circuit board are configured to be electrically coupled to each other.

12. The housing according to claim 11, wherein one of the electrically conductive signal coupling elements is configured as a connecting bond element.

13. The housing according to claim 11, wherein one of the electrically conductive signal coupling elements is a press-in contact which is pressed into a coupling element carrier which is held in place in the coupling region in the through opening.

14. A circuit arrangement having a housing configured according to claim 1 and a circuit board fastened in the circuit board compartment.

15. The circuit arrangement according to claim 14, further comprising the circuit board affixed in a first partial compartment; and a second circuit board affixed in a second partial compartment, wherein the circuit board and the second circuit board are coupled to each other via signal coupling elements to form an electric or electronic unit.
